(19) United States
(12) Patent Application Publication
(10) Pub. No.: US 2016/0126284 A1
(43) Pub. Date: May 5, 2016

(54) SOLID-STATE IMAGING DEVICE AND METHOD OF MANUFACTURING SOLID-STATE IMAGING DEVICE

(71) Applicant: Kabushiki Kaisha Toshiba, Minato-ku (JP)

(72) Inventors: Masanori KATO, Arakawa (JP); Takaaki MINAMI, Oita (JP)

(73) Assignee: Kabushiki Kaisha Toshiba, Minato-ku (JP)

(21) Appl. No.: 14/922,482

(22) Filed: Oct. 26, 2015

(30) Foreign Application Priority Data
Nov. 4, 2014 (JP) 2014-224768

(51) Int. Cl. H01L 27/146

(52) U.S. Cl. CPC H01L 27/14685; H01L 27/14689; H01L 27/14643; H01L 27/14612; H01L 27/1462

(57) ABSTRACT

According to an embodiment, provided is a solid-state imaging device. The solid-state imaging device is provided with a semiconductor layer, a gate of a pixel transistor, a gate of a peripheral circuit transistor, a silicon nitride film and a sidewall. A photo diode and a floating diffusion are provided in the semiconductor layer. The gate of the pixel transistor is provided on a surface of the semiconductor layer with the gate oxide film interposed therebetween. The gate of the peripheral circuit transistor is provided on the surface of the semiconductor layer with the gate oxide film interposed therebetween. The silicon nitride film is provided on an upper surface of the photo diode in the semiconductor layer with the gate oxide film interposed therebetween. The sidewall is provided on at least one side surface of the gate of the pixel transistor except for a side surface on the photo diode.

### CROSS-REFERENCE TO RELATED APPLICATIONS

This application is based upon and claims the benefit of priority from Japanese Patent Application No. 2014-224768, filed on Nov. 4, 2014; the entire contents of which are incorporated herein by reference.

### FIELD

Embodiments described herein relate generally to a solid-state imaging device and a method of manufacturing the solid-state imaging device.

### BACKGROUND

A conventional solid-state imaging device is provided with an imaging pixel unit in which a plurality of photoelectric conversion elements photoelectrically converting incident light into signal charge are two-dimensionally arranged, and a peripheral circuit unit that reads out the signal charge from the imaging pixel unit and performs signal processing. In some cases, the imaging pixel unit and the peripheral circuit unit are provided on the same semiconductor substrate.

In addition, in such a solid-state imaging device, a lightly doped drain (LDD) transistor is employed in some cases as a transistor in the peripheral circuit unit so as to improve operation characteristics of the peripheral circuit unit. This LDD transistor is provided with sidewalls that are provided on both side surfaces of a gate, an LDD region that is provided in a surface layer portion of the semiconductor substrate positioned below the sidewall, and source and drain regions that are provided adjacently to the LDD region at an outer side thereof.

Such a sidewall is formed such that an insulating film for forming the sidewall is formed on the entire surface of the semiconductor substrate including the imaging pixel unit and the peripheral circuit unit, and then, the entire surface is subjected to etchback using anisotropic dry etching.

Thus, there is a case in which a crystal defect occurs in the solid-state imaging device when a surface of the semiconductor substrate in the imaging pixel unit is damaged due to the etchback of the entire surface. An electron generating due to the crystal defect flows out from the photoelectric conversion element as a so-called dark current, or appears as a white spot in a captured image, thereby resulting image quality degradation.

### BRIEF DESCRIPTION OF THE DRAWINGS

FIG. 1 is a block diagram illustrating a schematic configuration of a solid-state imaging device according to an embodiment;

FIG. 2 is a schematic view illustrating an example of a circuit configuration of a pixel provided in the solid-state imaging device according to the embodiment;

FIG. 3 is a schematic plan view illustrating a part of a surface on a light receiving surface side of the pixel provided in the solid-state imaging device according to the embodiment;

FIG. 4 is an explanatory diagram illustrating a schematic cross-section taken along a line A-A′ of the pixel illustrated in FIG. 3 and a schematic cross-section of a transistor in a peripheral circuit unit;

FIGS. 5A to 5C are diagrams for describing a manufacturing process of a cross-sectional part taken along the line A-A′ of the pixel illustrated in FIG. 3 and a cross-sectional part of the peripheral circuit unit;

FIGS. 6A to 6C are diagrams describing the manufacturing process of the cross-sectional part taken along the line A-A′ of the pixel illustrated in FIG. 3 and the cross-sectional part of the peripheral circuit unit;

FIGS. 7A to 7C are diagrams describing the manufacturing process of the cross-sectional part taken along the line A-A′ of the pixel illustrated in FIG. 3 and the cross-sectional part of the peripheral circuit unit;

FIGS. 8A to 8C are diagrams describing the manufacturing process of the cross-sectional part taken along the line A-A′ of the pixel illustrated in FIG. 3 and the cross-sectional part of the peripheral circuit unit;

FIGS. 9A to 9C are diagrams describing a manufacturing process of a cross-sectional part taken along a line B-B′ of the pixel illustrated in FIG. 3;

FIGS. 10A to 10C are diagrams describing a manufacturing process of a cross-sectional part taken along a line C-C′ of the pixel illustrated in FIG. 3;

FIG. 11 is a schematic plan view illustrating a resist on a surface of the pixel illustrated in FIG. 3;

FIG. 12 is an explanatory diagram illustrating a schematic cross-section of an imaging pixel unit and a schematic cross-section of a transistor in a peripheral circuit unit according to a modified example of the embodiment;

FIGS. 13A to 13C are diagrams describing a manufacturing process of the cross-sectional part of the imaging pixel unit according to the modified example of the embodiment;

FIG. 14 is a schematic plan view illustrating a resist on a surface on a light receiving surface side of a pixel according to the modified example of the embodiment; and

FIG. 15 is an explanatory diagram illustrating a schematic cross-section of an imaging pixel unit and a schematic cross-section of a transistor in a peripheral circuit unit according to another modified example of the embodiment.

### DETAILED DESCRIPTION

According to this embodiment, provided is a solid-state imaging device. The solid-state imaging device is provided with a semiconductor layer, a gate of a pixel transistor, a gate of a peripheral circuit transistor, a silicon nitride film and a sidewall. A photo diode and a floating diffusion are provided in the semiconductor layer. The gate of the pixel transistor is provided on a surface of the semiconductor layer with a gate oxide film interposed therebetween. The gate of the peripheral circuit transistor is provided on the surface of the semiconductor layer with the gate oxide film interposed therebetween. The silicon nitride film is provided on an upper surface of the photo diode in the semiconductor layer with the gate oxide film interposed therebetween. The sidewall is provided at least one side surface except for a side surface on the photo diode side in the gate of the pixel transistor among both side surfaces of the gate of the pixel transistor, and both side surfaces of the gate of the peripheral circuit transistor.

Hereinafter, a description will be made in detail regarding the solid-state imaging device and a method of manufacturing the solid-state imaging device according to the embodiment with reference to the drawings. Incidentally, the invention is not limited by embodiments to be described hereinafter.

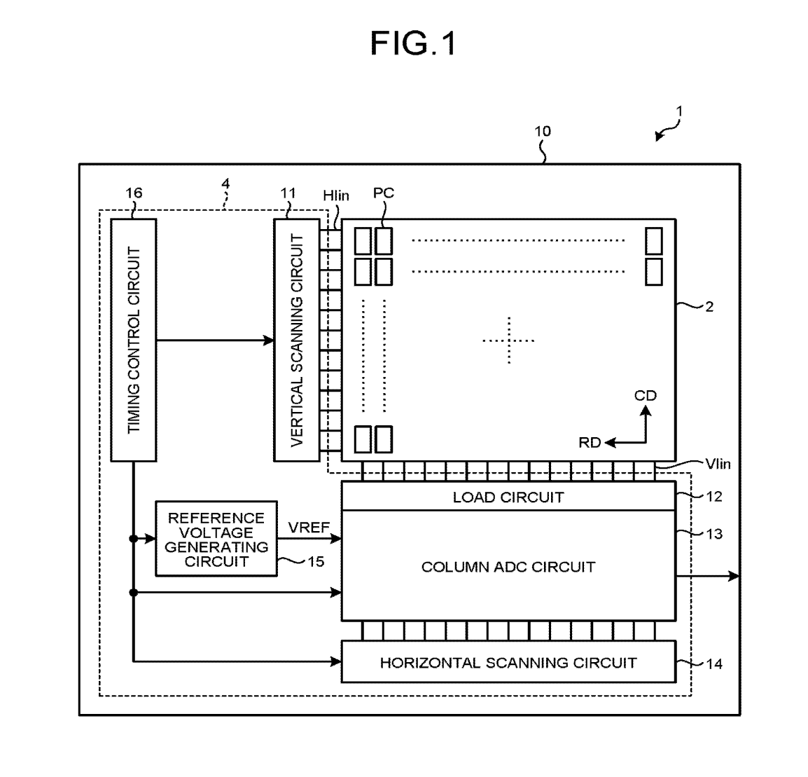

FIG. 1 is a block diagram illustrating a schematic configuration of a solid-state imaging device 1 according to the embodiment. As illustrated in FIG. 1, the solid-state imaging device 1 is provided with an imaging pixel unit 2 and a peripheral circuit unit 4 on a semiconductor substrate 10. In addition, the peripheral circuit unit 4 is provided with a vertical scanning circuit 11, a load circuit 12, a column analog digital converter (ADC) circuit 13, a horizontal scanning circuit 14, a reference voltage generating circuit 15, and a timing control circuit 16.

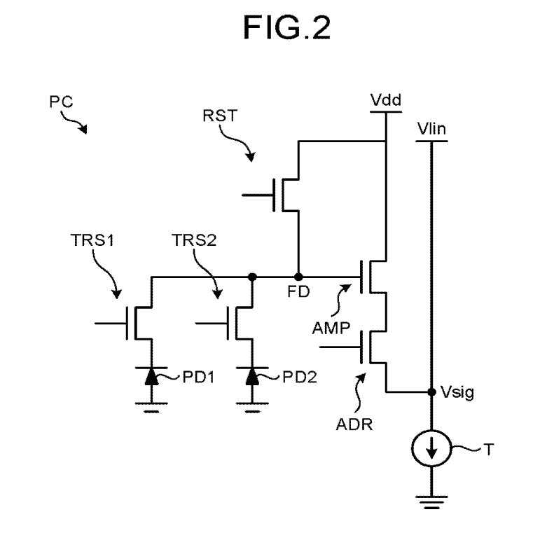

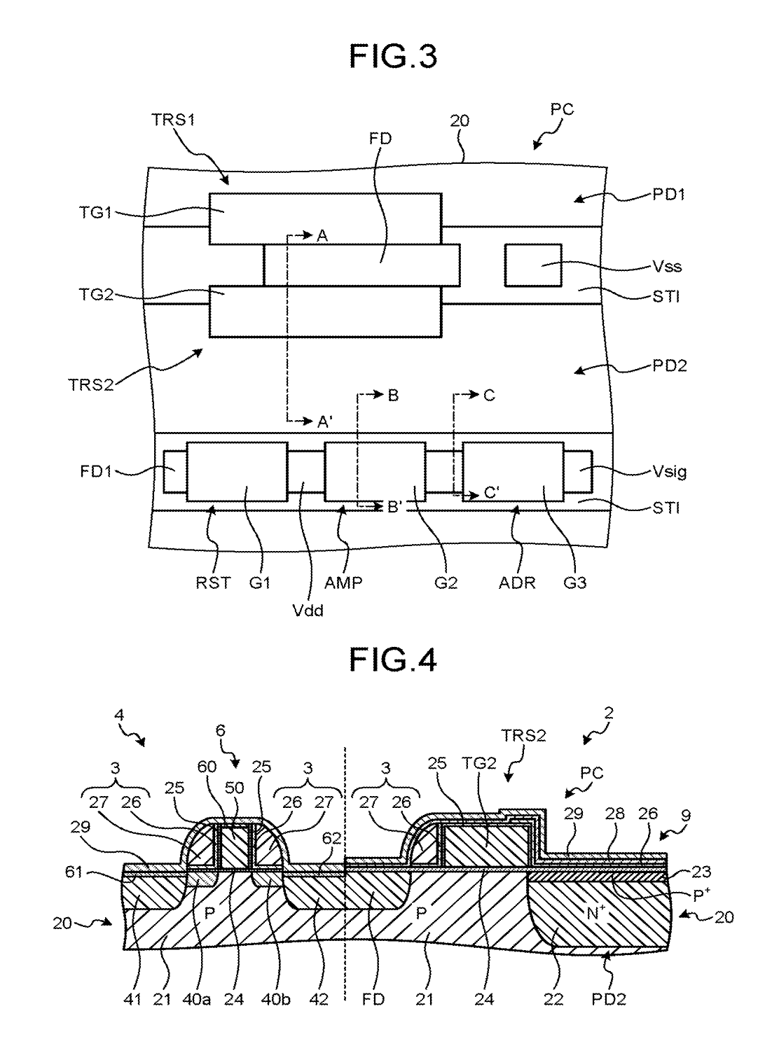

In the imaging pixel unit 2, pixels PC that photoelectrically converts and accumulates incident light are disposed in a two-dimensional array (matrix) form in a horizontal direction (row direction) RD and a vertical direction (column direction) CD. The pixel PC according to an embodiment has a two-pixel one-cell structure in which one unit cell includes two pixels. Incidentally, a circuit configuration and a physical structure of the pixel PC will be described later with reference to FIGS. 2 and 3.

In addition, the imaging pixel unit 2 is provided with a horizontal control line Hlin that performs control of reading the pixel PC in the horizontal direction RD, and a vertical signal line Vlin that transmits a voltage signal read out from the pixel PC in the vertical direction CD.

The vertical scanning circuit 11 sequentially selects the pixels PC to be read out in unit of row. The load circuit 12 reads out the voltage signal for each column from the pixels PC in the vertical signal line Vlin. The column ADC circuit 13 performs sampling of an electrical signal of each pixel PC for each column using correlated double sampling (CDS).

The horizontal scanning circuit 14 sequentially selects the pixels PC to be read out in unit of column. The reference voltage generating circuit 15 outputs a reference voltage VREF to the column ADC circuit 13. The reference voltage VREF is used for comparison with the voltage signal to be input to the column ADC circuit 13 via the vertical signal line Vlin. The timing control circuit 16 controls timing for reading out the voltage signal of each pixel PC with respect to the vertical scanning circuit 11.

In the solid-state imaging device 1, the pixel PC is selected for each row in the vertical direction CD by the vertical scanning circuit 11, and further, the pixel PC is selected for each column in the horizontal direction RD by the horizontal scanning circuit 14. Then, a source follower operation is performed between the selected pixels PC in the load circuit 12, and accordingly, the voltage signal read out from the pixel PC is sent to the column ADC circuit 13 via the vertical signal line Vlin.

Next, the circuit configuration and operation of the pixel PC will be briefly described with reference to FIG. 2. FIG. 2 is a schematic view illustrating an example of the circuit configuration of the pixel PC provided in the solid-state imaging device 1 according to the embodiment. As illustrated in FIG. 2, the pixel PC is provided with two photo diodes (photoelectric conversion elements) PD1 and PD2, and two transfer transistors TRS1 and TRS2. Further, the pixel PC is provided with a floating diffusion FD, an amplification transistor AMP, a reset transistor RST, and an address transistor ADR. Incidentally, an example of the physical layout thereof will be described with reference FIG. 3 to be described later.

Each of the photo diodes PD1 and PD2 has a cathode being connected to ground, and an anode being connected to each source of the transfer transistors TRS1 and TRS2. Each drain of the two transfer transistors TRS1 and TRS2 is connected to the one floating diffusion FD.

The respective transfer transistors TRS1 and TRS2 transfer signal charge photoelectrically converted by the photo diodes PD1 and PD2 to the floating diffusion FD when a transfer signal is input to a transfer gate. A source of the reset transistor RST is connected to the floating diffusion FD.

In addition, a drain of the reset transistor RST is connected to a power supply voltage line Vdd. The reset transistor RST resets a potential of the floating diffusion FD to a potential of a power supply voltage when a reset signal is input to a gate thereof.

In addition, a gate of the amplification transistor AMP is connected to the floating diffusion FD. A source of the amplification transistor AMP is connected to a drain of the address transistor ADR, and a drain thereof is connected to the power supply voltage line Vdd. In addition, a source of the address transistor ADR is connected to an output signal line Vsig. The vertical signal line Vlin is connected to a current source T via the output signal line Vsig.

In the pixel PC, when an address signal is input to a gate of the address transistor ADR, a signal amplified depending on a charge amount of the signal charge to be transferred to the floating diffusion FD is output from the amplification transistor AMP to the load circuit 12 via the address transistor ADR.

Next, the physical structure of the pixel PC will be described with reference to FIG. 3. FIG. 3 is a schematic plan view illustrating a part of a surface on a light receiving surface side of the pixel PC provided in the solid-state imaging device 1. As illustrated in FIG. 3, the pixel PC is provided with the two photo diodes PD1 and PD2 electrically separated by an element isolation region STI. In addition, the pixel PC is provided with the one floating diffusion FD between the two photo diodes PD1 and PD2. In other words, the structure of the pixel PC is the two-pixel one-cell structure in which the one floating diffusion FD is shared between the two photo diodes PD1 and PD2.

Transfer gates TG1 and TG2 of the transfer transistors TRS1 and TRS2 are disposed on the semiconductor layer 20 between each of the photo diodes PD1 and PD2 and the floating diffusion FD. In addition, a ground voltage line Vss is disposed adjacently to the floating diffusion FD in the semiconductor layer 20 with the element isolation region STI interposed therebetween.

In addition, a gate G1 of the reset transistor RST, a gate G2 of the amplification transistor AMP, and a gate G3 of the address transistor ADR are disposed in a region at an opposite side to the floating diffusion FD on the semiconductor layer 20 sandwiching the photo diode PD2.

In addition, the power supply voltage line Vdd is disposed between the reset transistor RST and the amplification transistor AMP in the semiconductor layer 20. Further, the output signal line Vsig is disposed adjacently to the address transistor ADR in the semiconductor layer 20, and a floating diffusion FD1 is disposed adjacently to the reset transistor RST. The floating diffusion FD1 is electrically connected to the floating diffusion FD via a metal wiring.

In the solid-state imaging device 1 according to the embodiment, the sidewall is formed on both the side surfaces of the gate of the transistor in the peripheral circuit unit 4 so as to form the source and drain regions on a surface layer portion in the semiconductor layer 20 under and around the gate.

The sidewall is formed such that an insulating film for forming the sidewall is formed on the entire surface of the semiconductor substrate 10 including the imaging pixel unit 2 and the peripheral circuit unit 4, and then, the entire surface is subjected to etchback using anisotropic dry etching.

Here, in a general solid-state imaging device, the sidewall is formed also on both the side surfaces of the gate of the transistor in the imaging pixel unit along with forming the sidewall on both the side surfaces of the gate of the transistor in the peripheral circuit unit.

In other words, the insulating film for the sidewall formed on the semiconductor layer is removed by the etchback even in the imaging pixel unit. Then, when the insulating film on the semiconductor layer at which the photo diode is positioned is removed, the surface layer portion of the semiconductor layer is damaged, and a crystal defect occurs, and further, electrons generated due to the crystal defect are accumulated in the photo diode, and flow out from the photo diode as a so-called dark current.

This is because, the insulating file on the semiconductor layer at which the photo diode is positioned is removed along with the formation of the sidewall on the side surface at the photo diode side in the gate of the transistor due to the etchback in the imaging pixel unit.

Thus, in the solid-state imaging device 1 according to the embodiment, a mask is formed on the photo diodes PD1 and PD2 in the semiconductor layer 20 in the pixel PC, and the sidewall is prepared on both the side surfaces of the gate of the transistor in the peripheral circuit unit 4 thereby reducing the generation of the dark current. Next, a description will be made specifically regarding the pixel PC according to the embodiment capable of reducing the generation of the dark current with reference to FIG. 4.

FIG. 4 is an explanatory diagram illustrating the schematic cross-section taken along a line A-A′ of the pixel PC illustrated in FIG. 3 and a schematic cross-section of the transistor in a peripheral circuit unit 4. In FIG. 4, the right side with respect to the dotted line indicated at the center of FIG. 4 is illustrated as the imaging pixel unit 2, and the left side with respect to the dotted line is illustrated as the peripheral circuit unit 4 in order to illustrate the imaging pixel unit 2 and the peripheral circuit unit 4 to be provided on the same the semiconductor substrate 10 in an easily understandable manner.

As illustrated in FIG. 4, the cross-sectional part of the pixel PC including the floating diffusion FD, the transfer transistor TRS2, and the photo diode PD2 has a structure illustrated in the right side with respect to the dotted line indicated at the center of FIG. 4. To be specific, the pixel PC is provided with the photo diode PD2, the floating diffusion FD, and a dark current suppressing region 23 in the semiconductor layer 20.

The photo diode PD2 is formed by a PN junction of a Si layer 21 to which ion implantation of a p-type low concentration impurity is performed, and a Si region 22 formed by performing ion implantation of an n-type high concentration impurity at a position having a predetermined depth in the p-type Si layer 21. The floating diffusion FD is formed by performing ion implantation of the n-type high concentration impurity into a surface layer portion of the p-type Si layer 21. The dark current suppressing region 23 is formed by performing ion implantation of a p-type high concentration impurity into a surface layer portion on the photo diode PD2 of the p-type Si layer 21.

In addition, the pixel PC is provided with the transfer gate TG2 made of, for example, polysilicon between the photo diode PD2 and the floating diffusion FD on the upper surface of the semiconductor layer 20 with a gate oxide film 24 interposed therebetween. A thermal oxide film 25 is formed on an upper surface and a side peripheral surface of the transfer gate TG2.

A sidewall 3 formed of two layers of which a lateral width increases as extending from a top surface of the transfer gate TG2 toward a bottom surface thereof is provided on the side surface on the floating diffusion FD side of the transfer gate TG2. The sidewall 3 is provided with a first sidewall forming film 26 which is made of, for example, SiN (silicon nitride), and provided on the side surface of the transfer gate TG2, and a second sidewall forming film 27 which is made of, for example, SiO2 (silicon oxide) and provided at an outer side of the first sidewall forming film 26. The sidewall 3 is formed at the same time as the sidewall to be formed on both the side surfaces of the gate of the transistor in the peripheral circuit unit 4 using the etchback.

In addition, the pixel PC is provided with a first silicide blocking film 28 to prevent of silicidation of the transistors TRS1, TRS2, ADR, AMP and RST in the imaging pixel unit 2. Further, the pixel PC is provided with an etching stopper film 29 to stop etching when a contact hole reaching the upper surface of the transfer gate TG2 is formed by etching.

The first sidewall forming film 26 is formed on the side surface on the floating diffusion FD side of the transfer gate TG2 as the sidewall 3. In addition, the first sidewall forming film 26 is also formed on the upper surface of the photo diode PD2 of the semiconductor layer 20, the side surface on the photo diode PD2 side of the transfer gate TG2, and a part of the upper surface of the transfer gate TG2.

The first silicide blocking film 28 is formed so as to cover a surface of the first sidewall forming film 26, the upper surface of the transfer gate TG2, a surface of the sidewall 3 provided on the side surface of the transfer gate TG2 and an upper surface of the floating diffusion FD of the semiconductor layer 20.

The etching stopper film 29 is formed so as to cover a surface of the first silicide blocking film 28. The first sidewall forming film 26, the first silicide blocking film 28, and the etching stopper film 29 all have the same properties of being made of, for example, SiN (silicon nitride) and preventing reflection of incident light.

The pixel PC is provided with an anti-reflection film 9 having a three-layer film structure of the first sidewall forming film 26 formed in a region corresponding to the photo diode PD2 on the semiconductor layer 20, the first silicide blocking film 28, and the etching stopper film 29.

The anti-reflection film 9 is a film to prevent the reflection of light incident to the photo diode PD2, and the anti-reflection film 9 is formed as a film stacked with the three layers made of SiN and having the same property in the pixel PC.

Next, a description will be made regarding the peripheral circuit unit 4 illustrated on the left side with respect to the dotted line indicated at the center of FIG. 4. Incidentally, the same reference numerals as the reference numerals illustrated in the imaging pixel unit 2 are attached to the same constituent elements as the constituent elements illustrated in the imaging pixel unit 2 among constituent elements illustrated in the peripheral circuit unit 4.

As illustrated in FIG. 4, the peripheral circuit unit 4 is provided with a gate 50 made of, for example, polysilicon on the upper surface of the semiconductor layer 20 with the gate oxide film 24 interposed therebetween. A silicide layer 60 is formed on an upper surface of the gate 50. In addition, the thermal oxide film 25 is formed on a side peripheral surface of the gate 50.

The sidewall 3 formed of two layers of which the lateral width increases as extending from a top surface of the gate 50 toward a bottom surface thereof is provided on both side surfaces of the gate 50. The sidewall 3 is provided with the first sidewall forming film 26 which is made of, for example, SiN (silicon nitride), and provided on the side surface of the gate 50, and the second sidewall forming film 27 which is made of, for example, SiO2 (silicon oxide) and provided at an outer side of the first sidewall forming film 26.

In addition, the peripheral circuit unit 4 is provided with lightly doped drain (LDD) regions 40a and 40b, a source region 41, and a drain region 42 in the semiconductor layer 20. The LDD regions 40a and 40b are configured to alleviate a magnetic field and suppress or prevent generation of a hot carrier, and are formed by performing ion implantation of the n-type high concentration impurity into the surface layer portion right below the sidewall 3 of the p-type Si layer 21.

The source region 41 is formed by performing ion implantation of the n-type high concentration impurity into the surface layer portion adjacent to the LDD region 40a of the p-type Si layer 21. The drain region 42 is formed by performing ion implantation of the n-type high concentration impurity into the surface layer portion adjacent to the LDD region 40b of the p-type Si layer 21. In addition, silicide layers 61 and 62 to reduce each electrical resistance of the source and drain regions 41 and 42 are formed on the source region 41 and the drain region 42 in the semiconductor layer 20. It is configured as above in a case where the transistor of the peripheral circuit unit 4 is an n-type transistor. In the case of a p-type transistor, the peripheral circuit unit 4 is formed such that an n-type low concentration impurity is implanted to the Si layer 21, and the p-type high concentration impurity is implanted to the LDD regions 40a and 40b and the source and drain regions 41 and 42.

In addition, the peripheral circuit unit 4 is provided with the etching stopper film 29 to stop etching when a contact hole reaching the upper surface of the gate 50 is formed by etching. The etching stopper film 29 is formed so as to cover an upper surface of the source region 41 of the semiconductor layer 20, a surface of the sidewall 3 provided on both the side surfaces of the gate 50, the upper surface of the gate 50, and an upper surface of the drain region 42 of the semiconductor layer 20.

In this manner, in the peripheral circuit unit 4, the LDD transistor 6 is configured by the gate oxide film 24, the gate 50, the p-type Si layer 21, the LDD regions 40a and 40b right below the sidewall 3, and the source and drain regions 41 and 42 adjacent to the LDD regions 40a and 40b.

In the solid-state imaging device 1 according to the embodiment, the sidewall 3 is formed on both the side surfaces of the gate 50 of the LDD transistor 6, but the sidewall 3 is not formed on the side surface on each side of the photo diodes PD1 and PD2 in the transfer gates TG1 and TG2. This is because the etchback is performed with the resist covering the upper surfaces of the photo diodes PD1 and PD2 of the semiconductor layer 20 as the mask after forming the first and second sidewall forming films 26 and 27 on the upper surface of the semiconductor layer 20 in the imaging pixel unit 2 and the peripheral circuit unit 4.

To be specific, at the time of the etchback, the resist covering the upper surfaces of the photo diodes PD1 and PD2 of the semiconductor layer 20, the side surface on each side of the photo diodes PD1 and PD2 of the transfer gates TG1 and TG2, and a part of the upper surface of the transfer gates TG1 and TG2 is used as the mask.

In this manner, the sidewall 3 is formed on the side surfaces on the floating diffusion FD side of the transfer gates TG1 and TG2 by the etchback, but the sidewall 3 is not formed on the side surface on each side of the photo diodes PD1 and PD2. In other words, a fact that the sidewall 3 is not formed on the side surface of the latter means that the upper surfaces of the photo diodes PD1 and PD2 of the semiconductor layer 20 are not damaged by the etchback.

In addition, the second sidewall forming film 27 formed on the upper surface of the first sidewall forming film 26 is removed by wet etching. Accordingly, the upper surfaces of the photo diodes PD1 and PD2 of the semiconductor layer 20 is prevented from etching of the surface of the semiconductor layer 20 by the first sidewall forming film 26. Thus, in the pixel PC, the upper surfaces of the photo diodes PD1 and PD2 of the semiconductor layer 20 are not damaged, and thus, it is possible to reduce generation of the dark current.

In addition, in the pixel PC, since the second sidewall forming film 27 is removed by the wet etching, it is possible to suppress variation in the film thickness of the first sidewall forming film 26 as compared to a case where the second sidewall forming film 27 is removed by dry etching. In addition, the first sidewall forming film 26 is one of films forming the anti-reflection film 9. Thus, in the pixel PC, the roughness of the film surface of the first sidewall forming film 26 is suppressed by removing the second sidewall forming film 27 using the wet etching so that it is possible to improve the anti-reflection function as compared to the case of using the dry etching.

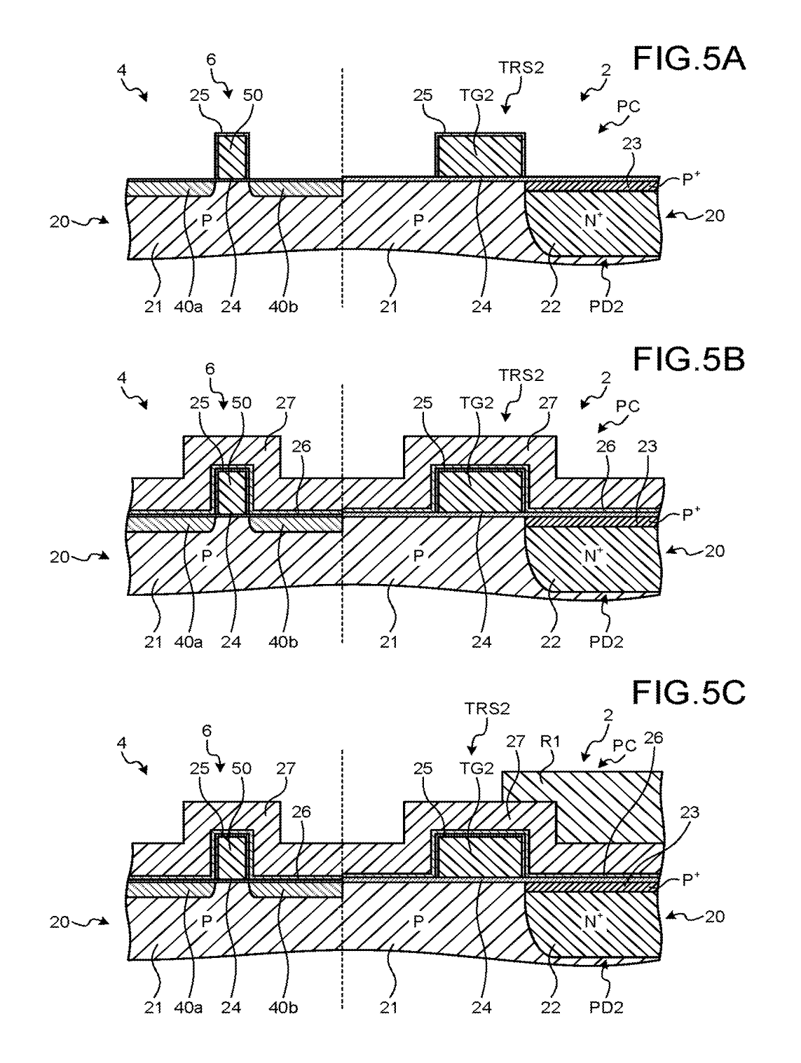

Next, a description will be made regarding an example of a method of manufacturing the solid-state imaging device 1 including a method of forming the imaging pixel unit 2 with reference to FIGS. 5A to 11. FIGS. 5A to 8C are diagrams describing a manufacturing process of the cross-sectional part taken along the line A-A′ of the pixel PC illustrated in FIG. 3, and the cross-sectional part of the peripheral circuit unit 4. Incidentally, in FIGS. 5A to 8C, the right side with respect to the dotted line indicated at each center of FIGS. 5A to 8C is illustrated as the imaging pixel unit 2, and the left side with respect to the dotted line is illustrated as the peripheral circuit unit 4 in order to illustrate the imaging pixel unit 2 and the peripheral circuit unit 4 to be provided on the same the semiconductor substrate 10 in an easily understandable manner.

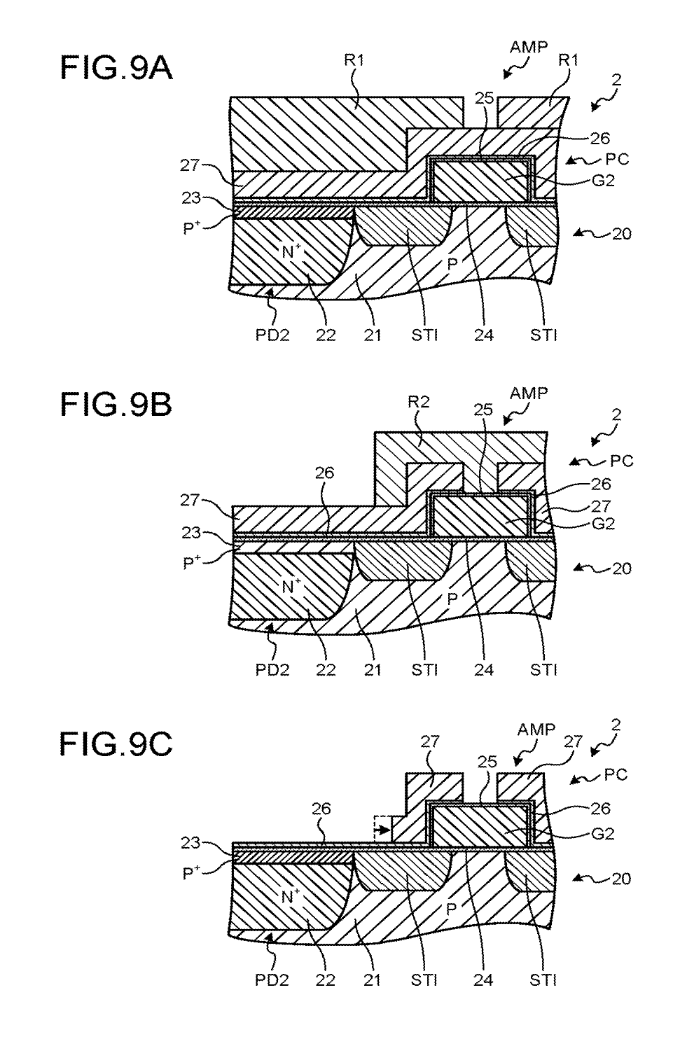

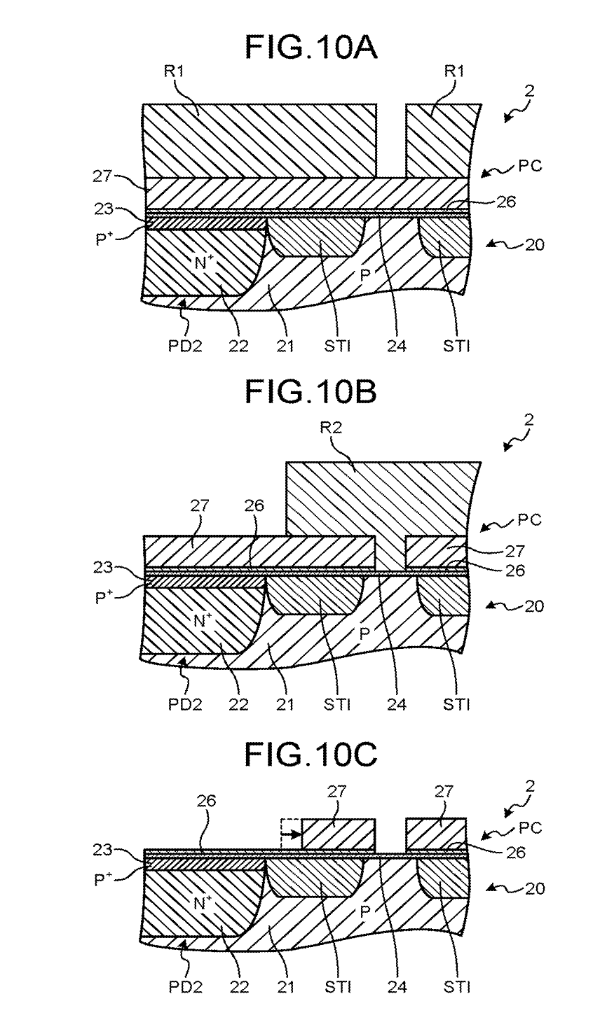

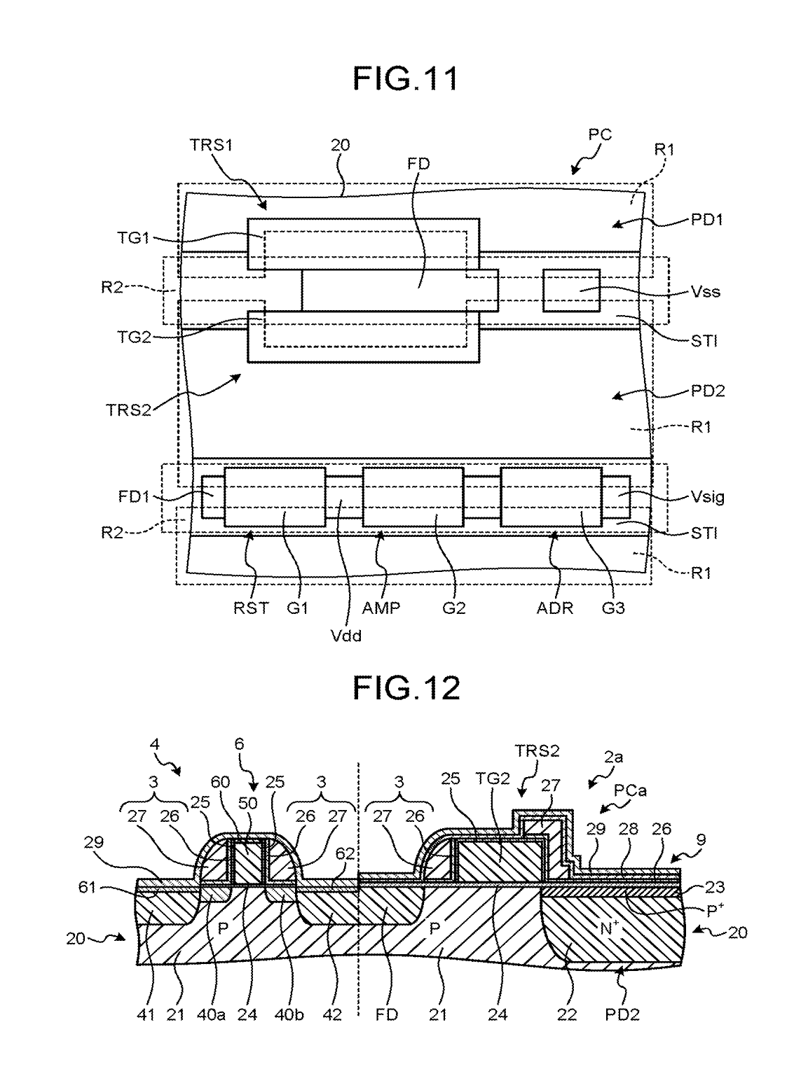

In addition, FIGS. 9A to 9C are diagrams describing a manufacturing process of a cross-sectional part taken along line B-B′ of the pixel PC illustrated in FIG. 3, and FIGS. 10A to 10C are diagrams describing a manufacturing process of a cross-sectional part taken along line C-C′ of the pixel PC illustrated in FIG. 3. In addition, FIG. 11 is a schematic plan view illustrating the resist on the surface of the pixel PC illustrated in FIG. 3. Incidentally, a method of manufacturing parts other than the imaging pixel unit 2 and the peripheral circuit unit 4 of the solid-state imaging device 1 is the same as that of a general CMOS image sensor. Thus, hereinafter, the manufacturing process of the parts representing the imaging pixel unit 2 and the peripheral circuit unit 4 of the solid-state imaging device 1 is selectively illustrated.

First, a description will be made regarding the manufacturing process of the cross-sectional part taken along the line A-A′ of the pixel PC illustrated in FIG. 3 and the cross-sectional part of the peripheral circuit unit 4 with reference to FIGS. 5A to 8C. As illustrated in FIG. 5A, the p-type Si layer 21 having a predetermined thickness is formed, for example, by performing epitaxial growth of a Si layer doped with the p-type low concentration impurity such as boron on the semiconductor substrate 10 (see FIG. 1) such as a Si wafer. Alternatively, the p-type Si layer 21 may be prepared, for example, by performing ion implantation of a p-type impurity such as boron onto a Si layer doped with the n-type low concentration impurity such as phosphorus and being subjected to the epitaxial growth. In this manner, the semiconductor layer 20 is formed.

Next, the gate oxide film 24 made of SiO₂ having a film thickness of 2 to 10 nm, for example, is formed on the upper surface of the semiconductor layer 20. Here, a film thickness of the gate oxide film 24 in the imaging pixel unit 2 is set to, for example, 10 nm, and a film thickness of the gate oxide film 24 in the peripheral circuit unit 4 is set to, for example, 2 nm.

Then, a polysilicon film for formation of the gate is formed on the supper surface of the semiconductor layer 20 with the gate oxide film 24 interposed therebetween, and the film is subjected to etching with the above-described resist covering each formation position of the transfer gate TG2 and the gate 50 as the mask. In this manner, the transfer gate TG2 is formed on the upper surface of the semiconductor layer 20 in the imaging pixel unit 2, and the gate 50 is formed on the upper surface of the semiconductor layer 20 in the peripheral circuit unit 4. In addition, the thermal oxide film 25 is formed on the surfaces of the transfer gate TG2 and the gate 50 by thermal oxidation.

Then, in the imaging pixel unit 2, the n-type Si region 22 is formed in the p-type Si layer 21 by performing ion implantation of an n-type impurity, for example, phosphorus, arsenic, or the like onto a predetermined depth position in the semiconductor layer 20 with the gate oxide film 24 interposed therebetween. The n-type Si region 22 is formed by self-alignment with the transfer gate TG2 as a mask, but may be formed by having the resist that covers the semiconductor layer 20 other than the formation position of the photo diode PD2 described above as a mask and performing ion implantation through the mask, before the transfer gate TG2 is formed. In this manner, in the semiconductor layer 20, a photoelectric conversion element, which is the photo diode PD2, is formed by the PN junction of the p-type Si layer 21 and the n-type Si region 22.

Subsequently, in the imaging pixel unit 2, the dark current suppressing region 23 is formed by performing ion implantation of the p-type high concentration impurity such as boron having a concentration of 1×10¹²/cm² to 1×10¹⁵/cm², for example, onto the surface layer portion on the photo diode PD2 in the semiconductor layer 20 with the gate oxide film 24 interposed therebetween. The dark current suppressing region 23 may be formed by performing ion implantation vertically or obliquely in the self-alignment having the transfer gate TG2 as the mask, or may be formed by performing ion implantation through the resist mask before or after forming the transfer gate TG2. Thereafter, an annealing process at a temperature of 900° C. to 1100° C., for example, is performed so as to recover the crystal defect of the semiconductor layer 20 caused by the ion implantation.

Next, in the peripheral circuit unit 4, the LDD regions 40a and 40b are formed in the p-type Si layer 21 by performing ion implantation of the n-type high concentration impurity, for example, phosphorus, arsenic, or the like onto the surface layer portion in the semiconductor layer 20 with the gate oxide film 24 interposed therebetween. The LDD regions 40a and 40b are formed by the self-alignment with the gate 50 as the mask.

Subsequently, as illustrated in FIG. 5B, the first sidewall forming film 26 made of SiN having a film thickness of 5 to 50 nm is formed, for example, using chemical vapor deposition (CVD) on the upper surface of the semiconductor layer 20 in the imaging pixel unit 2 and the peripheral circuit unit 4. Thereafter, the second sidewall forming film 27 made of SiO₂ having a film thickness of 10 to 100 nm is formed, for example, using tetraethoxysilane (TEOS) on the upper surface of the first sidewall forming film 26.

Then, as illustrated in FIG. 5C, a resist R1 covering the upper surface of the photo diode PD2 of the semiconductor layer 20 and a part of the upper surface on the photo diode PD2 side of the transfer gate TG2 is formed on the upper surface of the second sidewall forming film 27.

Here, a description will be made in more detail regarding a formation position of the resist R1 on the surface of the pixel PC with reference to FIG. 11. As illustrated in FIG. 11, the resist R1 is formed so as to cover the upper surfaces of the photo diodes PD1 and PD2, a part of the upper surface of each side of the photo diodes PD1 and PD2 of the transfer gates TG1 and TG2, and a part of the upper surfaces on the photo diode PD2 side of the gates G1 to G3. In addition, the resist R1 is formed also in a region opposite to the photo diode PD2 sandwiching the gates G1 to G3 in the pixel PC.

An end portion on each side of the transfer gates TG1 and TG2 in the resist R1 is raised up on the transfer gates TG1 and TG2. To be specific, the end portion on each side of the transfer gates TG1 and TG2 in the resist R1 is raised up by 50 nm, for example, from an end on each side of the photo diodes PD1 and PD2 on the upper surface of the transfer gates TG1 and TG2.

In this manner, at the time of the etchback, the first and second sidewall forming films 26 and 27 on the photo diodes PD1 and PD2 are not etched, and thus, the sidewall 3 is not formed on the side surface on each side of the photo diodes PD1 and PD2 of the transfer gates TG1 and TG2.

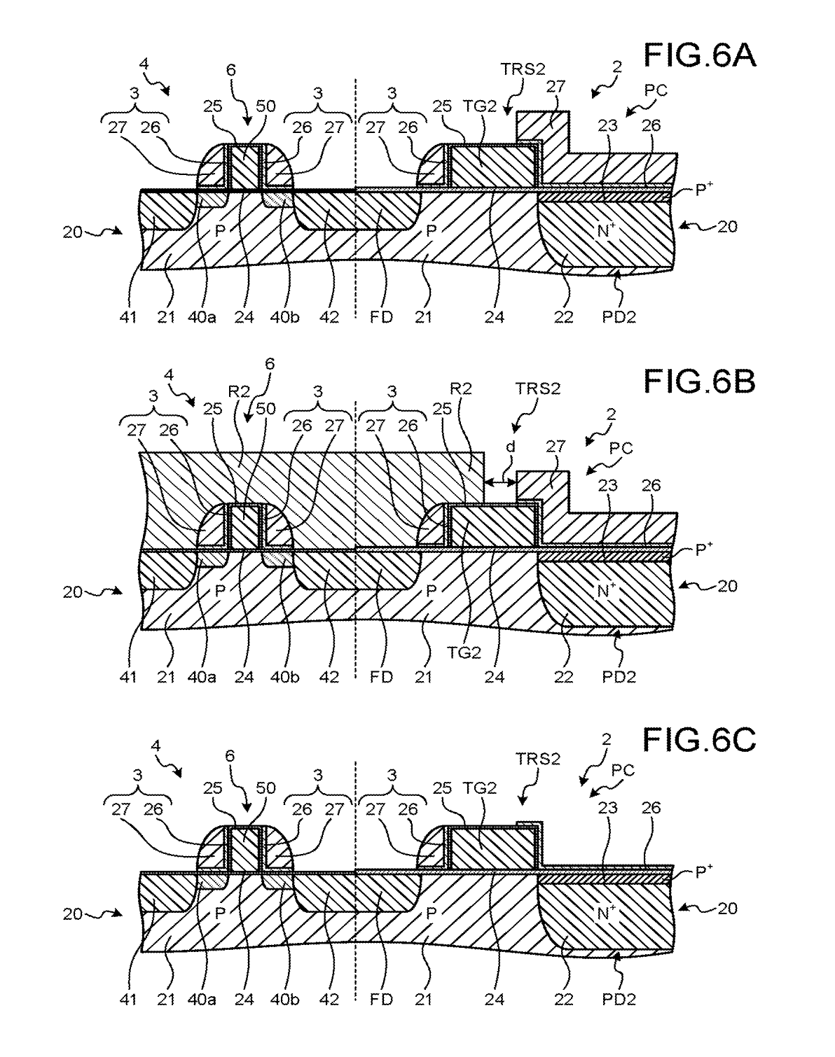

Returning to the description of FIG. 5C, the first sidewall forming film 26 and the second sidewall forming film 27 are subjected to the etchback by dry etching with the resist R1 as the mask. In this manner, as illustrated in FIG. 6A, the sidewall 3 is formed on both the side surfaces of the gate 50 of the LDD transistor 6, and the side surface on the floating diffusion FD side of the transfer gate TG2. Here, the second sidewall forming film 27 left by the etchback on the side surfaces of the gate 50 and the transfer gate TG2 with the first sidewall forming film 26 interposed therebetween becomes a spacer of the sidewall 3. Incidentally, the sidewall 3 is also formed on the side surface on the floating diffusion FD side of the transfer gate TG1, and each side surface on a side opposite to each of the gates G1 to G3 of the gates G1 to G3 (not illustrated).

Thereafter, the floating diffusion FD is formed in the p-type Si layer 21 by performing ion implantation of the n-type high concentration impurity for example, phosphorus and the like onto the formation position of the floating diffusion FD on the semiconductor layer 20 in the imaging pixel unit 2 with the gate oxide film 24 interposed therebetween.

In addition, in the peripheral circuit unit 4, the source region 41 and the drain region 42 are formed in the p-type Si layer 21 by performing ion implantation of the n-type high concentration impurity, for example, phosphorus, arsenic, or the like onto the formation positions of the source region 41 and the drain region 42 on the semiconductor layer 20 with the gate oxide film 24 interposed therebetween. The source region 41 and the drain region 42 are formed by the self-alignment with the gate 50 and the sidewall 3, respectively, as the mask. Thereafter, the annealing process at a temperature of 900° C. to 1100° C., for example, is performed so as to activate each region to which the ion implantation has been performed.

Subsequently, as illustrated in FIG. 6B, a resist R2 is formed on the upper surface of the semiconductor layer 20 in the peripheral circuit unit 4 and the imaging pixel unit 2. The resist R2 in the peripheral circuit unit 4 is formed so as to cover the LDD transistor 6 provided on the semiconductor layer 20. On the other hand, the resist R2 in the imaging pixel unit 2 is formed so as to cover the upper surface of the floating diffusion FD of the semiconductor layer 20, and a part of the upper surface on the floating diffusion FD side of the transfer gate TG2.

Here, a description will be made in more detail regarding a formation position of the resist R2 on the surface of the pixel PC with reference to FIG. 11 again. As illustrated in FIG. 11, the resist R2 is formed so as to cover the upper surface of the floating diffusion FD, the part of the upper surfaces on the floating diffusion FD side of the transfer gates TG1 and TG2, and the upper surfaces of the gates G1 to G3.

Returning to the description of FIG. 6B, an end portion on the transfer gate TG2 side of the resist R2 is not in contact with an end portion on the transfer gate TG2 side of the second sidewall forming film 27, and is separated from an end portion of the second sidewall forming film 27 by a predetermined distance d. Incidentally, similarly, an end portion on the transfer gate TG1 side of the resist R2 is also separated from an end portion on the transfer gate TG1 side of the second sidewall forming film 27 by the predetermined distance d (not illustrated). Here, the distance d is a distance to be defined depending on accuracy of an exposure machine, and preferably is, for example, 50 to 100 nm.

In this manner, in the pixel PC, it is possible to reliably remove the second sidewall forming film 27 raised up on the transfer gates TG1 and TG2 when removing the second sidewall forming film 27. Accordingly, the pixel PC can prevent the generation of dust caused by peeling off the second sidewall forming film 27 remaining on the upper surface of the transfer gates TG1 and TG2.

As illustrated in FIG. 6C, the second sidewall forming film 27, which is not covered by the mask, is removed by wet etching using a dilute hydrofluoric acid (DHF) or a buffered hydrofluoric acid (BHF) with the resist R2 as the mask. In the pixel PC, since the second sidewall forming film 27 is removed by the wet etching, it is possible to suppress the variation in the film thickness of the first sidewall forming film 26 as compared to a case where the second sidewall forming film 27 is removed by dry etching. In addition, the first sidewall forming film 26 is one of films forming the anti-reflection film 9. In addition, in the pixel PC, since the second sidewall forming film 27 is removed by wet etching, it is possible to suppress the roughness of the film surface of the first sidewall forming film 26 and to improve the anti-reflection function as compared to the case of using dry etching.

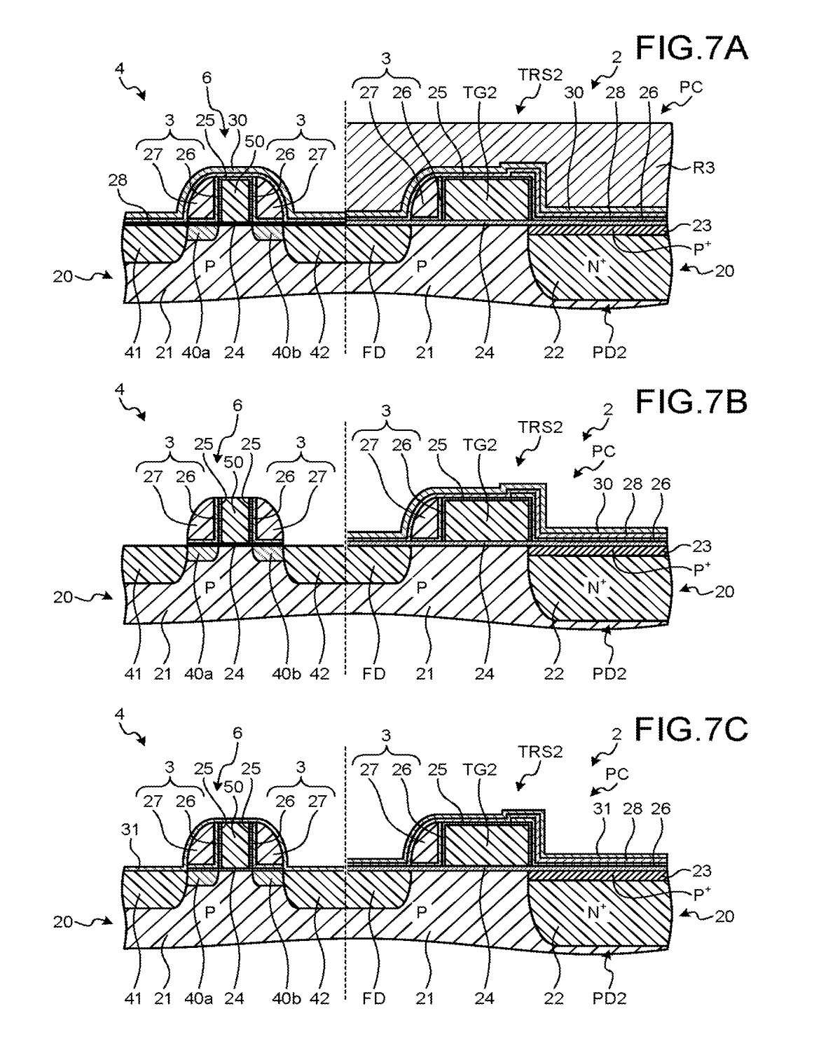

Subsequently, as illustrated in FIG. 7A, the first silicide blocking film 28, which is made of SiN and has a film thickness of 5 to 30 nm, is formed by, for example, the CVD method on the upper surface of the semiconductor layer 20 in the imaging pixel unit 2 and the peripheral circuit unit 4. Thereafter, the second silicide blocking film 30, which is made of SiO₂ and has a film thickness of 20 to 50 nm, is formed by, for example, a plasma TEOS method on the upper surface of the first silicide blocking film 28.

Then, a resist R3 is formed only on an upper surface of the second silicide blocking film 30 in the imaging pixel unit 2. Thereafter, as illustrated in FIG. 7B, the gate oxide film 24, the first silicide blocking film 28, and the second silicide blocking film 30, formed on the upper surface of the semiconductor layer 20 in the peripheral circuit unit 4, are removed by wet etching with the resist R3 as the mask. In addition, the first silicide blocking film 28 and the second silicide blocking film 30, formed on the surface of the gate 50 including the sidewall 3, are also removed by the wet etching. At this time, the thermal oxide film 25 formed on the upper surface of the gate 50 is also removed together. In this manner, the surface of the semiconductor layer 20 and the upper surface of the gate 50 in the peripheral circuit unit 4 are exposed.

Subsequently, as illustrated in FIG. 7C, the metal film 31 is formed by performing sputtering on the upper surface of the first silicide blocking film 28 and the upper surface of the semiconductor layer 20 in the peripheral circuit unit 4 after removing the second silicide blocking film 30 in the imaging pixel unit 2 by the wet etching. Examples of the metal film 31 includes a Ni (nickel) film, a Ti (titanium) film, a Co (cobalt) film, a W (tungsten) film, a Pt (platinum) film and the like.

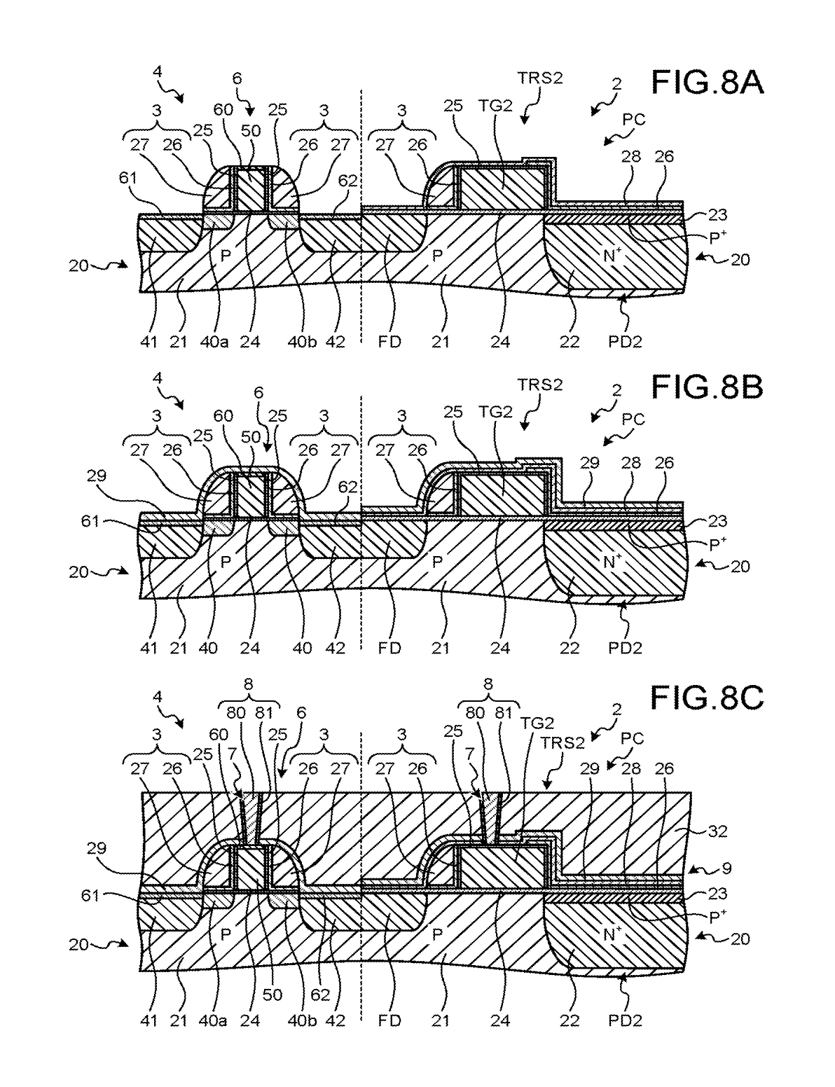

Then, as illustrated in FIG. 8A, the annealing process is performed so as to cause the silicon on the surface of the semiconductor layer 20 and the silicon on the upper surface of the gate 50, which are exposed, to react with the metal film 31 in the peripheral circuit unit 4, and thereby, forming the silicide layers 60, 61 and 62. Examples of the silicide layers 60, 61 and 62 include NiSi (nickel silicide), TiSi2 (titanium silicide), CoSi2 (cobalt silicide), WSi2 (tungsten silicide), and PtSi (platinum silicide), and the like.

Then, the peripheral circuit unit 4 is subjected to the silicidation, and then the unreacted metal film 31 in the imaging pixel unit 2 and the peripheral circuit unit 4 is removed by wet etching.

Next, as illustrated in FIG. 8B, the etching stopper film 29 for forming the contact hole, which is made of SiN, and has a film thickness of 20 to 50 nm, is formed using, for example, the CVD on the upper surface of the semiconductor layer 20 in the imaging pixel unit 2 and the peripheral circuit unit 4.

Thereafter, as illustrated in FIG. 8C, an interlayer insulating film 32 made of SiO₂ is formed using, for example, the CVD on the upper surface of the etching stopper film 29. Then, a surface of the interlayer insulating film 32 is planarized using for example, chemical mechanical polishing (CMP).

Next, a resist having a predetermined shape (not illustrate) for forming the contact hole is formed on an upper surface of the interlayer insulating film 32 in the imaging pixel unit 2. The first silicide blocking film 28, the etching stopper film 29, and the interlayer insulating film 32 on the transfer gate TG2 in the imaging pixel unit 2 are etched with the above-described resist as the mask, and thereby, forming a contact hole 7. In addition, in the same manner, the etching stopper film 29 and the interlayer insulating film 32 on the gate 50 in the peripheral circuit unit 4 are etched, and thereby, forming the contact hole 7.

Then, an insulating film 81 is formed on an inner surface of the contact hole 7, and a conducting layer 80 is embedded inside the contact hole 7, and thereby, forming the contact plug 8. Thereafter, a multilayer wiring layer (not illustrated) is formed on the upper surface of the interlayer insulating film 32.

In this manner, in the imaging pixel unit 2, the anti-reflection film 9 having the three-layer film structure of the first sidewall forming film 26, the first silicide blocking film 28, and the etching stopper film 29 is formed in the region corresponding to the photo diodes PD1 and PD2 on the semiconductor layer 20.

A film thickness of the anti-reflection film 9 is determined by a sum of the film thickness of three of the first sidewall forming film 26, the first silicide blocking film 28, and the etching stopper film 29. Since the film thickness of the first sidewall forming film 26 does not vary due to the etching in this embodiment, it is possible to easily adjust the film thickness of the anti-reflection film 9.

Next, a description will be made regarding the manufacturing processes of the cross-sectional parts taken along the line B-B′ and the line C-C′ of the pixel PC illustrated in FIG. 3 with reference to FIGS. 9A to 9C and 10A to 10c. Here, a description will be made from a state in which the second sidewall forming film 27 is formed on the upper surface of the semiconductor layer 20 in the imaging pixel unit 2. Incidentally, the same reference numerals are attached to the same constituent elements as the constituent elements illustrated in the cross-sectional part taken along the line A-A′ of the pixel PC illustrated in FIG. 3 among constituent elements illustrated in the cross-sectional part.

As illustrated in FIGS. 9A and 10A, the resist R1 having a predetermined shape is formed on the upper surface of the second sidewall forming film 27. To be specific, the resist R1 illustrated in FIG. 9A is formed so as to cover the upper surface of the photo diode PD2 of the semiconductor layer 20 and a part of the upper surface on the photo diode PD2 side of the gate G2 of the amplification transistor AMP. In addition, a resist R1 illustrated in FIG. 10A is formed so as to cover the upper surface of the photo diode PD2 of the semiconductor layer 20 and the upper surface of the element isolation region STI adjacent to the photo diode PD2 of the semiconductor layer 20.

As illustrated in FIG. 9A (see also FIG. 11), the end portions on each side of the gates G1 to G3 of the resist R1 are raised up on the gates G1 to G3. To be specific, the end portion on each side of the gates G1 to G3 of the resist R1 is raised up by 50 nm, for example, from an end on the photo diodes PD2 side of each upper surface of the gates G1 to G3.

Then, the first sidewall forming film 26 and the second sidewall forming film 27, which are not covered by the mask, are subjected to the etchback by dry etching with the resist R1 as the mask.

Thereafter, in the cross-sectional part taken along the line B-B′ of the pixel PC, the resist R2, which covers the upper surface of the gate G2 and the upper surface of the second sidewall forming film 27 rising up on the gate G2, is formed as illustrated in FIG. 9B. To be specific, as illustrated in FIG. 9B (see also FIG. 11), an end portion on the photo diode PD2 side of the resist R2 is positioned on the element isolation region STI adjacent to the photo diode PD2 provided in the semiconductor layer 20. In addition, an end portion at an opposite side of the end portion on the photo diode PD2 side of the resist R2 is also positioned on the element isolation region STI provided in the semiconductor layer 20.

On the other hand, in the cross-sectional part taken along the line C-C′ of the pixel PC, the resist R2 is formed so as to cover the upper surface of the second sidewall forming film 27 positioned on the element isolation region STI adjacent to the photo diode PD2 as illustrated in FIG. 10B. To be specific, as illustrated in FIG. 10B (see also FIG. 11), the end portion on the photo diode PD2 side of the resist R2 is positioned on the element isolation region STI adjacent to the photo diode PD2 provided in the semiconductor layer 20. In addition, an end portion at an opposite side of the end portion on the photo diode PD2 side of the resist R2 is also positioned on the element isolation region STI provided in the semiconductor layer 20.

As described above, the end portion on the photo diode PD2 side of the resist R2 is set to a position which is not beyond a boundary between the photo diode PD2 and an element isolation region STI. Accordingly, the second sidewall forming film 27 does not remain on the boundary between the photo diode PD2 and the element isolation region STI in the semiconductor layer 20.

Then, the second sidewall forming film 27, which is not covered by the mask, is removed by wet etching with the resist R2 as the mask. As illustrated in FIGS. 9C and 10C, the second sidewall forming film 27 positioned on the photo diode PD2, which is not covered by the resist R2, is removed, and the second sidewall forming film 27 positioned on the element isolation region STI covered by the resist R2 remains. In addition, a part of the end portion of the second sidewall forming film 27 positioned on the element isolation region STI is removed by being soaked with a wet liquid.

In this manner, in the pixel PC, the end portion of the second sidewall forming film 27 positioned on the element isolation region STI serves a role of absorbing the wet liquid. In this manner, the pixel PC can reduce a load to the surface of the first sidewall forming film 26 by the wet etching. In addition, in the pixel PC, the upper surface of the element isolation region STI in the semiconductor layer 20 is constantly covered by the first sidewall forming film 26. Accordingly, in the pixel PC, the upper surface of the element isolation region STI of the semiconductor layer 20 is prevented from etching of the surface of the semiconductor layer 20 by the first sidewall forming film 26. Thus, in the pixel PC, the element isolation region STI is not scrapped when the second sidewall forming film 27 is removed by the wet etching.

As described above, in the solid-state imaging device 1 according to the embodiment, the sidewall 3 is formed on both the side surfaces of the gate 50 of the LDD transistor 6, but the sidewall 3 is not formed on the side surface on each side of the photo diodes PD1 and PD2 of the transfer gates TG1 and TG2. This is because the etchback is performed with the resist covering the upper surfaces of the photo diodes PD1 and PD2 of the semiconductor layer 20 as the mask after forming the first and second sidewall forming films 26 and 27 on the upper surface of the semiconductor layer 20 in the imaging pixel unit 2 and the peripheral circuit unit 4.

To be specific, at the time of the etchback, the resist R1 covering the upper surfaces of the photo diodes PD1 and PD2 of the semiconductor layer 20, the side surface on each side of the photo diodes PD1 and PD2 of the transfer gates TG1 and TG2, and the part of the upper surface of the transfer gates TG1 and TG2 is used as the mask.

In this manner, the sidewall 3 is formed on the side surfaces on the floating diffusion FD side of the transfer gates TG1 and TG2 by the etchback, but the sidewall 3 is not formed on the side surface on each side of the photo diodes PD1 and PD2. In other words, a fact that the sidewall 3 is not formed on the side surface of the latter means that the upper surfaces of the photo diodes PD1 and PD2 of the semiconductor layer 20 are not damaged by the etchback.

In addition, the second sidewall forming film 27 formed on the upper surface of the first sidewall forming film 26 is removed by wet etching. Accordingly, the upper surfaces of the photo diodes PD1 and PD2 of the semiconductor layer 20 is prevented from etching of the surface of the semiconductor layer 20 by the first sidewall forming film 26. Thus, in the pixel PC, the upper surfaces of the photo diodes PD1 and PD2 of the semiconductor layer 20 are not damaged, and thus, it is possible to reduce generation of the dark current.

In addition, in the pixel PC, since the second sidewall forming film 27 is removed by the wet etching, it is possible to suppress variation in the film thickness of the first sidewall forming film 26 as compared to a case where the second sidewall forming film 27 is removed by dry etching. In addition, the first sidewall forming film 26 is one of films forming the anti-reflection film 9. Thus, in the pixel PC, the roughness of the film surface of the first sidewall forming film 26 is suppressed by removing the second sidewall forming film 27 using the wet etching so that it is possible to improve the anti-reflection function as compared to the case of using the dry etching.

Incidentally, the configuration of the imaging pixel unit according to an embodiment is not limited to the configuration illustrated in FIG. 4. Next, a description will be made regarding an imaging pixel unit according to a modified example of the embodiment with reference to FIG. 12. FIG. 12 is an explanatory diagram illustrating an imaging pixel unit 2a according to a modified example of the embodiment. Incidentally, in FIG. 12, the right side with respect to the dotted line indicated at the center of FIG. 12 is illustrated as the imaging pixel unit 2a, and the left side with respect to the dotted line is illustrated as the peripheral circuit unit 4. In addition, in the following description, the same reference numerals as the reference numerals illustrated in FIG. 4 are attached to the same constituent elements as the constituent elements illustrated in FIG. 4 among the constituent elements of the imaging pixel unit 2a and the peripheral circuit unit 4 illustrated in FIG. 12 and the description thereof will be omitted.

As illustrated in FIG. 12, the imaging pixel unit 2a is provided with the second sidewall forming film 27 on the side surface on the photo diode PD2 side of the transfer gate TG2. To be specific, the second sidewall forming film 27 has one end portion being raised up on a part of the upper surface on the photo diode PD2 side of the transfer gate TG2, and the other end portion being positioned on the photo diode PD2 of the semiconductor layer 20.

The second sidewall forming film 27 is a part left for the absorption of the wet liquid when removing the second sidewall forming film 27 on the photo diode PD2 of the semiconductor layer 20 by the wet etching. In this manner, the imaging pixel unit 2a can reduce the load applied to the surface of the first sidewall forming film 26 caused by the wet liquid by the remaining part of the second sidewall forming film 27. Incidentally, the second sidewall forming film 27 is also formed on the side surface on the photo diode PD1 side of the transfer gate TG1 in the same manner (not illustrated).

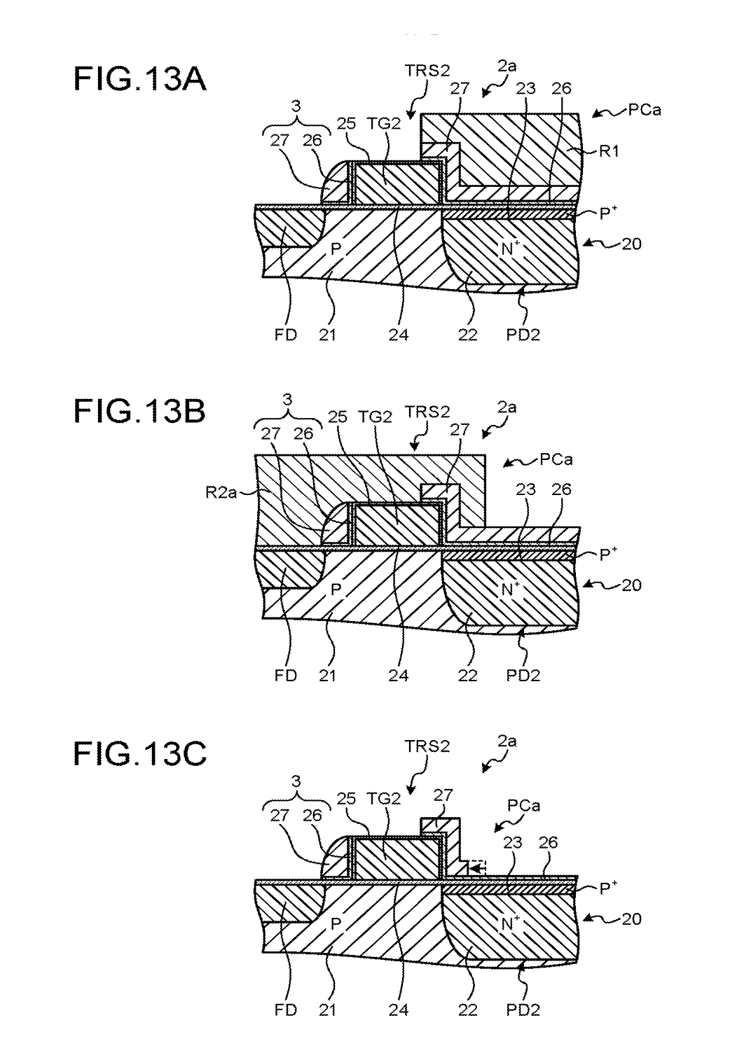

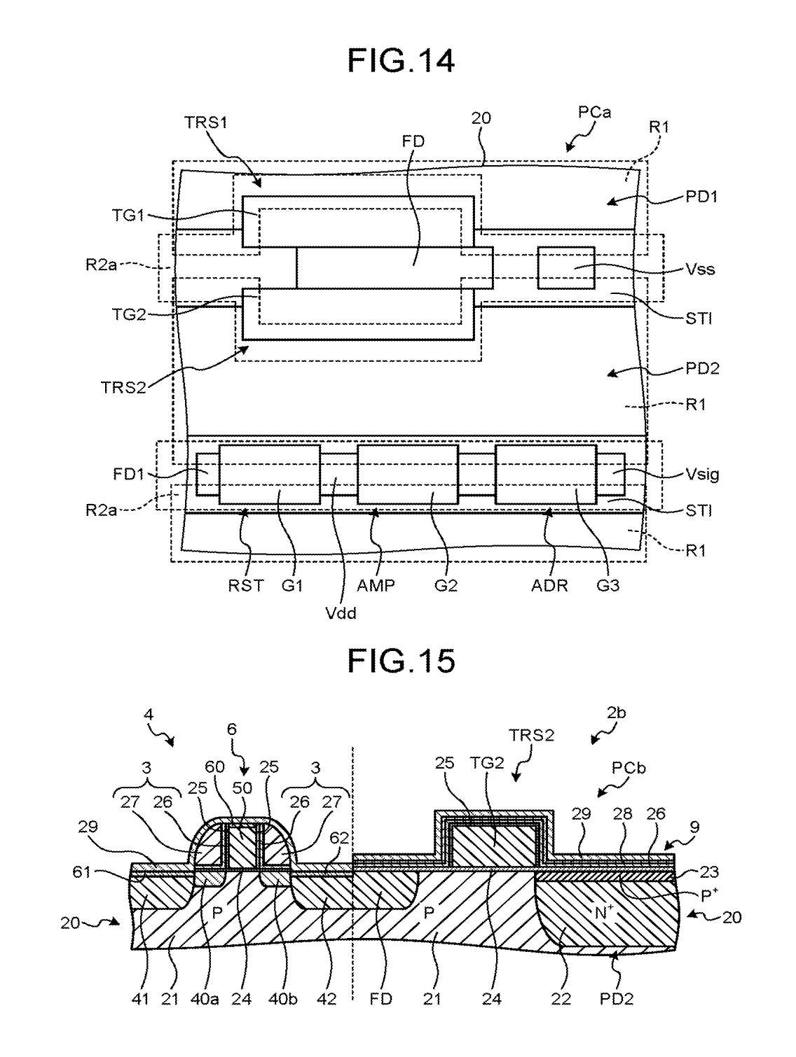

A manufacturing process of the imaging pixel unit 2a will be described with reference to FIGS. 13A to 13C and 14. FIGS. 13A to 13C are diagrams describing a manufacturing process of a cross-sectional part of the imaging pixel unit 2a according to the modified example of the embodiment. FIG. 14 is a schematic plan view illustrating a resist on a surface on a light receiving surface side of a pixel PCa according to the modified example of the embodiment. Here, a description will be made from a state in which the sidewall 3 is formed on the side surface on the floating diffusion FD side of the transfer gate TG2 by the dray etching with the resist R1 as the mask.

As illustrated in FIG. 13A, the resist R1, which is formed so as to cover the upper surface of the photo diode PD2 of the semiconductor layer 20 and the part of the upper surface on the photo diode PD2 side of the transfer gate TG2, is removed.

Next, as illustrated in FIG. 13B, a resist R2a is formed to cover the upper surface of the transfer gate TG2, and the upper surface of the second sidewall forming film 27 raised up on the transfer gate TG2. To be specific, as illustrated in FIGS. 13B and 14, an end portion on each side of the photo diodes PD1 and PD2 of the resist R2a is positioned on the photo diodes PD1 and PD2 of the semiconductor layer 20.

Then, the second sidewall forming film 27, which is not covered by the mask, is removed by wet etching with the resist R2a as the mask. As illustrated in FIG. 13C, the second sidewall forming film 27 positioned on the photo diodes PD1 and PD2, which are not covered by the resist R2a, is removed, and the second sidewall forming film 27 positioned on the photo diodes PD1 and PD2 covered by the resist R2a remains. In addition, a part of the end portion of the second sidewall forming film 27 positioned on the photo diodes PD1 and PD2 is removed by being soaked with a wet liquid.

In this manner, the end portion of the second sidewall forming film 27 positioned on the photo diodes PD1 and PD2 serve a role of absorbing the wet liquid. In this manner, the imaging pixel unit 2a can reduce the load applied to the surface of the first sidewall forming film 26 caused by the wet liquid by the remaining part of the second sidewall forming film 27.

In addition, even in such an embodiment, the imaging pixel unit 2a can reduce the generation of the dark current since the upper surfaces of the photo diodes PD1 and PD2 of the semiconductor layer 20 are not damaged by the etchback.

Next, a description will be made regarding an imaging pixel unit according to another modified example of the embodiment with reference to FIG. 15. FIG. 15 is an explanatory diagram illustrating an imaging pixel unit 2b according to the another modified example of the embodiment. Incidentally, in FIG. 15, the right side with respect to the dotted line indicated at the center of FIG. 15 is illustrated as the imaging pixel unit 2b, and the left side with respect to the dotted line is illustrated as the peripheral circuit unit 4. In addition, in the following description, the same reference numerals as the reference numerals illustrated in FIG. 4 are attached to the same constituent elements as the constituent elements illustrated in FIG. 4 among the constituent elements of the imaging pixel unit 2b and the peripheral circuit unit 4 illustrated in FIG. 15 and the description thereof will be omitted.

As illustrated in FIG. 15, in the imaging pixel unit 2b, the upper surface and both the side surfaces of the transfer gate TG2 are covered by a three-layer stacked film of the first sidewall forming film 26, the first silicide blocking film 28 and the etching stopper film 29. To be specific, in the imaging pixel unit 2b, the sidewall, prepared by the etchback, is not provided on the both the surfaces of the transfer gate TG2 of the transfer transistor TRS2. Incidentally, similarly, the sidewall is not provided on both the side surfaces of the transfer gate TG1 of the transfer transistor TRS1 in the imaging pixel unit 2b either (not illustrated).

Different from the above-described imaging pixel unit 2, the imaging pixel unit 2b is not provided with the sidewall on the floating diffusion FD side of the transfer gate TG2. This is because the etchback, in which a resist covering the entire surface of the imaging pixel unit 2 except for the regions of the gates G1 to G3 is used as the mask, is performed after forming the first and second sidewall forming films 26 and 27.

In this manner, the sidewall is not formed on the side surfaces on the floating diffusion FD side of the transfer gates TG1 and TG2 due to the etchback. In other words, a fact that the sidewall is not formed on the side surface of the latter means that the upper surfaces of the floating diffusions FD1 and FD2 of the semiconductor layer 20 are not damaged by the etchback.

This is because the surface of the semiconductor layer 20 is prevented from being etched by the first sidewall forming film 26 formed on the upper surface of the floating diffusion FD of the semiconductor layer 20. Accordingly, a pixel PCb can reduce the generation of the dark current since the upper surface of the floating diffusion FD is not damaged.

Incidentally, the floating diffusion FD in the semiconductor layer 20 is formed by ion implantation through the first and second sidewall forming films 26 and 27 after forming the sidewall 3 on both side walls of the gate 50 of the LDD transistor 6 in the peripheral circuit unit 4, or through the first sidewall forming film 26 after removing the second sidewall forming film 27. In addition, the floating diffusion FD may be formed before forming the sidewalls 3 on both the side walls of the gate 50 of the LDD transistor 6 in the peripheral circuit unit 4.

In addition, the second sidewall forming film 27 is removed by the wet etching, and at this time, a resist covering only the regions of the gates G1 to G3 is used as the mask in the imaging pixel unit 2b.

In addition, even in such an embodiment, the imaging pixel unit 2b can reduce the generation of the dark current since the upper surfaces of the photo diodes PD1 and PD2 of the semiconductor layer 20 are not damaged.

Incidentally, the Si layer 21 is set to a p-type in the above-described embodiments, but it is possible to prepare the n-type Si region 22 by setting the Si layer 21 of the imaging pixel units 2, 2a and 2b to be an n-type and injecting the p-type impurity into the corresponding layer 21 to separate the pixel. In addition, in a case where the Si layer 21 is set to the n-type, it may be configured such that the source and drain regions 41 and 42 and the LDD regions 40a and 40b are formed using the p-type impurity in the peripheral circuit unit 4. In addition, in the peripheral circuit unit 4, both the p-type transistor and the n-type transistor are formed regardless of whether the Si layer 21 is the p-type or the n-type.

In addition, in the above-described embodiments, shallow trench isolation (STI) is used as the element isolation region, but the element isolation region may be formed using local oxidation of silicon (LOCOS) or ion implantation.

In addition, in the above-described embodiments, the description has been made exemplifying the pixels PC, PCa and PCb having the two-pixel and one-cell structure, but the same effect can be obtained with a pixel having another structure such as a one-pixel and one-cell structure or a four-pixel and one-cell structure.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a semiconductor layer that is provided with a photo diode and a floating diffusion;
a gate of a pixel transistor that is provided on a surface of the semiconductor layer with a gate oxide film interposed therebetween;
a gate of a peripheral circuit transistor that is provided on the surface of the semiconductor layer with the gate oxide film interposed therebetween;
a silicon nitride film that is provided on an upper surface of the photo diode in the semiconductor layer with the gate oxide film interposed therebetween; and
a sidewall that is provided on at least one side surface except for a side surface on the photo diode side of the gate of the pixel transistor among both side surfaces of the gate of the pixel transistor and both side surfaces of the gate of the peripheral circuit transistor.

2. The solid-state imaging device according to claim 1, wherein
the sidewall includes a silicon nitride film provided on the side surface of the gate of the pixel transistor and on the side surface of the gate of the peripheral circuit transistor, and a spacer formed of a silicon oxide film provided at an outer side of the silicon nitride film.

3. The solid-state imaging device according to claim 1, wherein
the silicon nitride film provided on the upper surface of the photo diode extends from the side surface on the photo diode side of the gate of the pixel transistor to a part of an upper surface thereof.

4. The solid-state imaging device according to claim 1, comprising
a silicon nitride film that is provided on an upper surface of the floating diffusion in the semiconductor layer with the gate oxide film interposed therebetween.

5. The solid-state imaging device according to claim 1, comprising:
a lightly doped drain (LDD) region that is provided right below the sidewall in an upper layer part of the semiconductor layer; and
a source region and a drain region that are provided in regions sandwiching the LDD region in the upper layer part, and adjacent to the LDD region.

6. The solid-state imaging device according to claim 4, wherein
the silicon nitride film provided on the upper surface of the photo diode has a thicker film thickness than the silicon nitride film provided on the upper surface of the floating diffusion.

7. The solid-state imaging device according to claim 4, wherein
the silicon nitride film provided on the upper surface of the photo diode has the same film thickness as the silicon nitride film provided on the upper surface of the floating diffusion.

8. The solid-state imaging device according to claim 5, comprising
a silicon nitride film that is provided on an upper surface of the source region and the drain region in the semiconductor layer, the silicon nitride film provided on the upper surface of the source region and the drain region having a thinner film thickness than the silicon nitride film provided on the upper surface of the photo diode.

9. The solid-state imaging device according to claim 1, comprising
a silicon oxide film provided on the side surface on the photo diode side of the gate of the pixel transistor, the silicon oxide film extending to a part of the upper surface of the photo diode in the semiconductor layer.

10. The solid-state imaging device according to claim 1, wherein
the silicon nitride film provided on the upper surface of the photo diode is a film that prevents reflection of incident light.

11. A method of manufacturing a solid-state imaging device, the method comprising:
forming a gate oxide film, a gate of a pixel transistor, and a gate of a peripheral circuit transistor on a semiconductor layer;
forming a photo diode and a floating diffusion in the semiconductor layer;
sequentially forming a silicon nitride film and a silicon oxide film on an upper surface of the semiconductor layer including the gate of the pixel transistor and the gate of the peripheral circuit transistor;
forming a first resist that selectively covers at least the silicon oxide film on a formation region of the photo diode;
forming a sidewall by performing etchback on the silicon nitride film and the silicon oxide film with the first resist as a mask;
forming a second resist that selectively covers at least a part of a region other than the formation region of the first resist in the semiconductor layer; and
removing the silicon oxide film remaining on the formation region of the first resist by wet etching with the second resist as a mask.

12. The method of manufacturing the solid-state imaging device according to claim 11, wherein
in the case of forming the first resist, an end surface on the gate side of the pixel transistor of the first resist reaches a part of an upper surface of the gate of the pixel transistor.

13. The method of manufacturing the solid-state imaging device according to claim 11, wherein
in the case of forming the second resist, an end surface on the gate side of the pixel transistor of the second resist does not reach an end surface of the gate side of the pixel transistor of the silicon oxide film remaining in the formation region of the first resist.

14. The method of manufacturing the solid-state imaging device according to claim 11, wherein
in the case of forming the second resist, an end surface on the gate side of the pixel transistor of the second resist reaches a part of an upper surface of the photo diode in the semiconductor layer.

15. The method of manufacturing the solid-state imaging device according to claim 11, comprising:
forming a lightly doped drain (LDD) region right below the sidewall in an upper layer part of the semiconductor layer; and
forming a source region and a drain region, which are adjacent to the LDD region, in a region sandwiching the LDD region in the upper layer part.
